(19) United States
(12) Patent Application Publication
(10) Pub. No.: US 2025/0031281 A1
(43) Pub. Date: Jan. 23, 2025

(54) SUBSTRATE SUPPORTING MEMBER AND SUBSTRATE PROCESSING APPARATUS INCLUDING THE SAME

(71) Applicant: SAMSUNG ELECTRONICS CO., LTD., Suwon-si (KR)

(72) Inventors: Sanghyun LIM, Suwon-si (KR); Youngho HWANG, Suwon-si (KR); Juno PARK, Suwon-si (KR); Kyoungwhan OH, Suwon-si (KR); Youngkyun IM, Suwon-si (KR); Jaehong LIM, Suwon-si (KR); Chulmin CHO, Suwon-si (KR); Seok HEO, Suwon-si (KR)

(21) Appl. No.: 18/389,721

(22) Filed: Dec. 19, 2023

(30) Foreign Application Priority Data
Jul. 17, 2023 (KR) 10-2023-0092571

(51) Int. Cl. H05B 3/26; G03F 7/00

(52) U.S. Cl. CPC H05B 3/26; G03F 7/70716; G03F 7/70791

(57) ABSTRACT

A substrate supporting member and a substrate processing apparatus including the same are provided. The substrate supporting member includes a plate having at least one heating zone. A heating member is on a first surface of the plate and located in the at least one heating zone. The heating member extends along a circumferential direction of the plate and is configured to heat a substrate supported by the plate. A first electrode is on the first surface of the plate and is connected to an inner side surface of the heating member. A second electrode is on the first surface of the plate and is connected to an outer side surface of the heating member. The heating member has a stair-step configuration such that a thickness of the heating member increases from the second electrode toward the first electrode.

### CROSS-REFERENCE TO RELATED APPLICATION

This application claims priority to and the benefit of Korean Patent Application No. 10-2023-0092571 filed in the Korean Intellectual Property Office on Jul. 17, 2023, the disclosure of which is incorporated herein by reference in its entirety.

### BACKGROUND

### 1. Field

The present disclosure relates to a substrate supporting member and a substrate processing apparatus including the same.

### 2. Description of the Related Art

In order to manufacture a semiconductor device, various processes such as photo, etching, deposition, ion implantation, and cleaning are performed. Among them, the photo process is a process for forming a pattern and plays an important role in achieving high integration of semiconductor devices.

The photo process is mainly composed of a coating process, an exposure process, and a developing process, and a bake process is performed before and after the exposure process. The bake process is a process of heat-treating a substrate, in which, when a substrate is placed on a heating plate, the substrate is heat-treated through a heating plate provided inside the heating plate.

Generally, a heating wire is provided on the heating plate, and heat generated through the heating wire diffuses into the heating plate, whereby the substrate may be heat-treated. The heat generated through the heating wire may not be sufficiently diffused into the heating plate, and thus a temperature deviation may occur within the heating plate.

### SUMMARY

The present disclosure provides a substrate supporting member with an improved plate temperature deviation and a substrate processing apparatus including the same.

A substrate supporting member may include a plate having at least one heating zone. A heating member is on a first surface of the plate and is in the at least one heating zone and extends along a circumferential direction of the plate. The heating member is configured to heat a substrate supported by the plate. A first electrode is on the first surface of the plate, and is connected to an inner side surface of the heating member. A second electrode is on the first surface of the plate, and is connected to an outer side surface of the heating member. The heating member has a stair-step configuration such that a portion of the heating member that is adjacent the first electrode has a first thickness that is greater than a second thickness of a portion of the heating member that is adjacent the second electrode.

A substrate processing apparatus may include a housing, a plate positioned within the housing, and at least one heating member on a first surface of the plate, wherein the at least one heating member is configured to heat a substrate supported by the plate. The at least one heating member extends along a circumferential direction of the plate. A first electrode is connected to an inner side surface of the at least one heating member, and a second electrode extends along the circumferential direction of the plate, and is connected to an outer side surface of the at least one heating member. The at least one heating member has a stair-step configuration such that a thickness of the at least one heating member decreases as a distance of the at least one heating member from a center of the plate increases.

A substrate supporting member may include a plate having a plurality of heating zones arranged circumferentially around a central portion of the plate. A plurality of heating members are on a first surface of the plate. Each of the plurality of heating members is in a respective one of the plurality of heating zones and is configured to heat a substrate supported by the plate. A first electrode is in a central portion of the plate and is connected to an inner side surface of each of the plurality of heating members. A second electrode is connected to an outer side surface of each of the plurality of heating members. Each of the plurality of heating members has a stair-step configuration such that a thickness thereof decreases as a distance of each of the plurality of heating members from the central portion of the plate increases.

A heating member of a substrate processing apparatus according to embodiments may be a planar heating element. Accordingly, an area of the heating member contacting the plate is relatively increased, and the time required to change the plate to a preset temperature may be shortened.

In addition, since the heating member extends along the circumferential direction of the plate and the heating member may include the stair-step configuration whose thickness decreases as the distance from center of the plate increases, the resistance value of the heating member may be maintained constant along the radial direction of the plate. Therefore, the temperature deviation of the substrate supporting member due to heating of the heating member may be decreased, and the reliability of the substrate processing apparatus may be improved.

### BRIEF DESCRIPTION OF THE DRAWINGS

FIG. 1 is a top plan view showing a substrate processing facility according to an embodiment.

FIG. 2 is a cross-sectional view of the substrate processing facility of FIG. 1 viewed from the direction A-A.

FIG. 3 is a cross-sectional view of the substrate processing facility of FIG. 1 viewed from the direction B-B.

FIG. 4 is a cross-sectional view showing a substrate processing apparatus according to an embodiment.

FIG. 5 is a bottom view showing a substrate supporting member of a substrate processing apparatus according to an embodiment.

FIG. 6 is a bottom view showing a plurality of heating zones of a heating plate according to an embodiment.

FIG. 7 is a bottom view showing a plurality of heating zones of a heating plate according to another embodiment.

FIG. 8 is a perspective view showing a heating plate according to an embodiment.

FIG. 9 is a cross-sectional view showing a substrate supporting member of a substrate processing apparatus according to an embodiment and corresponding to line A-A′ of FIG. 5.

FIG. 10 is a drawing showing a temperature distribution of a substrate supporting member according to Comparative Example.

FIG. 11 is a drawing showing a temperature distribution of a substrate supporting member according to an embodiment.

FIG. 12 is a cross-sectional view showing a substrate supporting member according to another embodiment and corresponding to line A-A′ of FIG. 5.

FIG. 13 is a cross-sectional view showing still a substrate supporting member according to another embodiment and corresponding to line A-A′ of FIG. 5.

FIG. 14 is a bottom view showing a substrate supporting member of a substrate processing apparatus according to another embodiment.

FIG. 15 is a cross-sectional view showing a substrate supporting member according to another embodiment and corresponding to line B-B′ of FIG. 14.

FIG. 16 to FIG. 21 are intermediate step drawings for explaining a manufacturing method of a substrate supporting member of a substrate processing apparatus according to an embodiment.

FIG. 22 and FIG. 23 are intermediate step drawings for explaining a manufacturing method of a substrate supporting member of a substrate processing apparatus according to another embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the scope of the present disclosure.

In order to clearly describe the present invention, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top (i.e., from above the target portion), and the phrase “in a cross-sectional view” or “on a cross-section” means viewing a cross-section formed by vertically cutting a target portion from the side.

A facility of this embodiment may be used to perform a photolithography process on a substrate such as a semiconductor wafer or a flat panel display panel. In particular, the facility of this embodiment may be connected to an exposure apparatus and used to perform a coating process and a developing process on a substrate. Hereinbelow, a case where a wafer is used as a substrate will be described as an example.

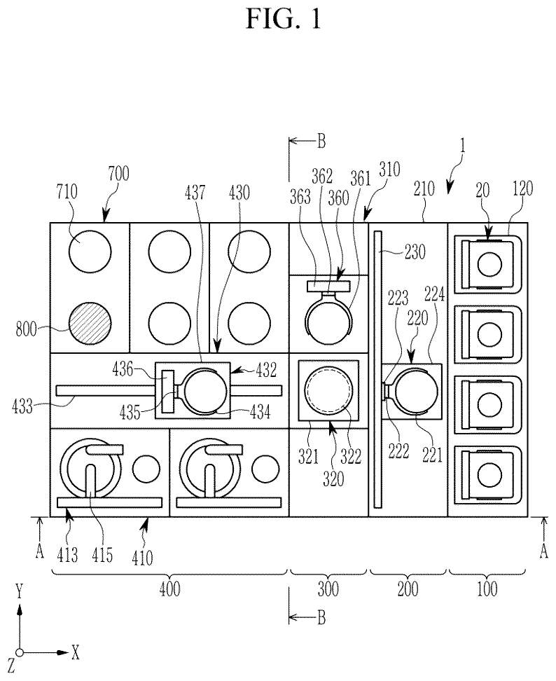

A substrate processing facility including a substrate processing apparatus according to an embodiment is described with reference to FIG. 1 to FIG. 3.

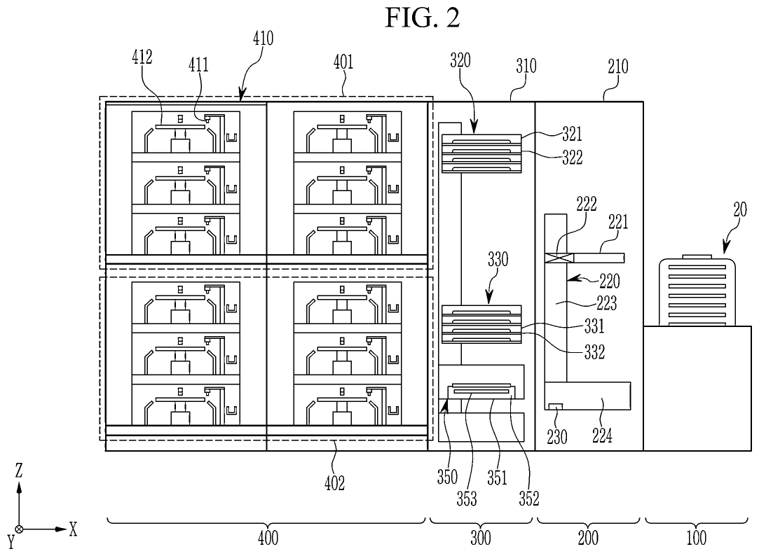

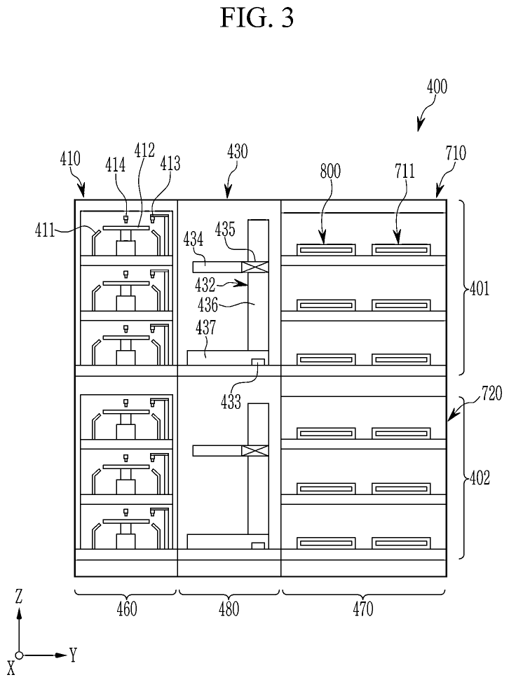

FIG. 1 is a top plan view showing a substrate processing facility according to an embodiment. FIG. 2 is a cross-sectional view of the substrate processing facility of FIG. 1 viewed from the direction A-A. FIG. 3 is a cross-sectional view of the substrate processing facility of FIG. 1 viewed from the direction B-B.

Referring to FIG. 1 to FIG. 3, a substrate processing facility 1 may include a load port 100, an index module 200, a first buffer module 300, coating and developing module 400. The load port 100, the index module 200, the first buffer module 300, the coating and developing module 400 may be sequentially disposed in one direction.

The load port 100 includes a cassette 20 accommodating a substrate W and a support member 120 supporting the cassette 20.

The cassette 20 may move while the substrate W is accommodated therein. The cassette 20 may have a structure that may be sealed from the outside. For example, a front open unified pod (FOUP) having a front door may be used as the cassette 20. Accordingly, the substrate W may move while being stored in the cassette 20.

The support member 120 may support the cassette 20. The support members 120 may be arranged in a line along the second direction (Y direction). In one embodiment, the support member 120 may be provided in plurality (i.e., in a plural quantity). For example, although four supporting members 120 are shown in FIG. 1 and FIG. 2, it is not limited thereto.

The index module 200 may transport the substrate W between the cassette 20 and the first buffer module 300. The index module 200 may include a frame 210, an index robot 220, and a guide rail 230.

The frame 210 may have a substantially hollow rectangular parallelepiped shape. The frame 210 may be disposed between the load port 100 and the first buffer module 300. The index robot 220 and the guide rail 230 may be disposed within the frame 210.

The index robot 220 may have a structure capable of 4-axis driving such that a hand 221 directly handling the substrate W may move and rotate in a first direction (X direction), the second direction (Y direction), and a third direction (Z direction).

The index robot 220 may include the hand 221, a first robot arm 222, a supporting member 223, and a pedestal 224. The hand 221 may be fixed to the first robot arm 222. The hand 221 may move and rotate in the first direction (X direction), the second direction (Y direction), and the third direction (Z direction). The first robot arm 222 may have a stretchable structure and a rotatable structure. The supporting member 223 may extend along the third direction (Z direction). The first robot arm 222 may be coupled to the supporting member 223 so as to be movable along an extension direction of the supporting member 223. The supporting member 223 may be fixed to the pedestal 224.

The guide rail 230 may extend along the second direction (Y direction). The pedestal 224 may be coupled to the guide rail 230 so as to be linearly movable along an extension direction of the guide rail 230. In addition, although not shown, the frame 210 may further include a door opener for opening and closing a door of the cassette 20.

The first buffer module 300 may include a frame 310, a first buffer 320, a second buffer 330, a cooling chamber 350, and a first buffer robot 360.

The frame 310 may have a substantially hollow rectangular parallelepiped shape. The frame 310 may be disposed between the index module 200 and the coating and developing module 400. The first buffer 320, the second buffer 330, the cooling chamber 350, and the first buffer robot 360 may be disposed within the frame 310. The cooling chamber 350 (FIG. 2), the second buffer 330 (FIG. 2), and the first buffer 320 may sequentially be disposed along the third direction (Z direction).

The first buffer 320 may be disposed at a height corresponding to a coating module 401 of the coating and developing module 400, described later. The second buffer 330 and the cooling chamber 350 may be disposed at a height corresponding to a developing module 402 of the coating and developing module 400, described later.

The first buffer 320 and the second buffer 330 may temporarily store the substrates W, respectively

Each of the first buffer 320 and the second buffer 330 may include housings 321 and 331 and a plurality of supporting members 322 and 332. The supporting members 322 and 332 may be disposed within the housings 321 and 331. The supporting members 322 and 332 may be disposed apart from each other along the third direction (Z direction). One substrate W may be disposed on each of the supporting members 322 and 332. The substrate W disposed on the supporting members 322 and 332, respectively may move by the index robot 220, the first buffer robot 360, and a developing robot of the developing module 402 to be described later. The first buffer 320 may have a structure substantially similar to that of the second buffer 330. However, the number of supports 322 provided in the first buffer 320 and the number of supports 332 provided in the second buffer 330 may be the same or different.

The first buffer robot 360 may be disposed apart from the second buffer 330, the cooling chamber 350, and the first buffer 320 in the second direction (Y direction). The first buffer robot 360 may transport the substrate W between the first buffer 320 and the second buffer 330. The first buffer robot 360 may include a hand 361, a second robot arm 362, and a support 363. The hand 361 may be fixed to the second robot arm 362. The hand 361 may be movable and rotatable in the second direction (Y direction) and the third direction (Z direction). The second robot arm 362 may have a stretchable structure. The second robot arm 362 may be coupled to the support 363. The second robot arm 362 may linearly move along the support 363 in the third direction (Z direction). The first buffer robot 360 may have a structure capable of 2-axis driving such that the hand 361 may move and rotate in the second direction (Y direction) and the third direction (Z direction).

The cooling chamber 350 may cool the substrate W. The cooling chamber 350 may include a housing 351 and a cooling plate 352. The cooling plate 352 may include a cooling means 353 configured to cool the substrate W. As the cooling means 353, various methods such as cooling by coolant or cooling using a thermoelectric element may be used. In addition, a lift pin assembly (not shown) may be provided in the cooling chamber 350 to position the substrate W on the cooling plate 352. The housing 351 may include an opening on one side. Through the opening of the housing 351, the index robot 220 and the developing robot provided in the developing module 402 to be described later may carry in or take out the substrate W from the cooling plate 352.

The coating and developing module 400 may perform a process of applying a photoresist on the substrate W before the exposure process and a process of developing a pattern on the substrate W after the exposure process.

The coating and developing module 400 may include the coating module 401 and the developing module 402. The coating module 401 and the developing module 402 be may disposed along the third direction (Z direction). For example, the coating module 401 may be disposed in an upper portion of the developing module 402.

In an embodiment, the coating module 401 may perform a heat treatment process (e.g., a heating process) on the substrate W after a process of applying a photoresist to the substrate W. In addition, the developing module 402 may perform a heat treatment process (e.g., a heating process) before the process of developing a pattern on the substrate W.

The coating module 401 may include a resist coating unit 410, a first bake unit 710, and a transfer chamber 430. The resist coating unit 410, the transfer chamber 430, and the first bake unit 710 may sequentially be disposed along the second direction (Y direction). Accordingly, the resist coating unit 410 and the first bake unit 710 may be disposed spaced apart from each other in the second direction (Y direction) interposing the transfer chamber 430, as illustrated.

In an embodiment, the resist coating unit 410 and the first bake unit 710 may be provided in plurality. For example, the resist coating unit 410 and the first bake unit 710 may be provided in plural quantities, respectively, in the first direction (X direction) and the third direction (Z direction). FIG. 2 and FIG. 3 show that six resist coating units 410 and the first bake unit 710 are respectively provided, but are not limited thereto.

The transfer chamber 430 may be disposed in parallel to the first buffer 320 of the first buffer module 300 in the first direction (X direction). The transfer chamber 430 may include a coating robot 432 and a guide rail 433. The coating robot 432 may transport the substrate W between the first bake unit 710, the resist coating unit 410, and the first buffer 320 of the first buffer module 300. The guide rail 433 may be extended in the first direction (X direction). The guide rail 433 may guide the coating robot 432 to linearly move in the first direction (X direction).

The coating robot 432 may include a hand 434, a third robot arm 435, a supporting member 436, and a pedestal 437. The hand 434 may be fixed to the third robot arm 435. The third robot arm 435 may have a stretchable structure. The third robot arm 435 may be coupled to the supporting member 436 so as to be linearly movable in the third direction (Z direction) along the supporting member 436. The supporting member 436 may be fixed to the pedestal 437. The pedestal 437 may be coupled to the guide rail 433 to be movable along the guide rail 433.

All of the resist coating units 410 may have the same structure

However, the type of photoresist used in respective resist coating units 410 may be different from each other. For example, a chemical amplification resist may be used as the photoresist. The resist coating unit 410 may apply a photoresist on the substrate W. The resist coating unit 410 may include a housing 411, a support plate 412, and a nozzle 413. The housing 411 may have a cup shape with an open top. The support plate 412 may be disposed within the housing 411, and may support the substrate W. The support plate 412 may be rotatably provided. The nozzle 413 may supply photoresist onto the substrate W placed on the support plate 412. The nozzle 413 may have a circular tubular shape. The nozzle 413 may supply the photoresist to the center of the substrate W. The discharge port of the nozzle 413 may be provided in a slit shape. In an embodiment, additionally, the resist coating unit 410 may further include a nozzle that supplies cleaning solution such as deionized water in order to clean a surface of the substrate W applied with photoresist.

The first bake unit 710 may perform a heat treatment process with respect to the substrate W. For example, the first bake unit 710 may perform the heat treatment process with respect to the substrate W after the process of applying the photoresist and/or before the developing process.

The first bake unit 710 includes a cooling member 711 and a substrate processing apparatus 800.

The cooling member 711 may cool the substrate W heat-processed by the substrate processing apparatus 800. The cooling member 711 may have a circular plate shape. A cooling means such as cooling water or a thermoelectric element is provided inside the cooling member 711. Accordingly, the substrate W on the cooling member 711 may be cooled to a temperature equal to or close to room temperature.

The substrate processing apparatus 800 may perform a heat treatment process with respect to the substrate W. For example, the substrate processing apparatus 800 may perform the heat treatment process with respect to the substrate W after the process of applying the photoresist and/or before the developing process.

In one embodiment, the substrate processing apparatus 800 may be a substrate heating apparatus that heat-processes the substrate W.

In more detail, the substrate processing apparatus 800 may apply the photoresist on the substrate W, and then heat the substrate W to a preset temperature such that surface properties of the substrate W and/or the properties of the photoresist applied on the substrate W may be changed. Accordingly, a volatile material included in the photoresist applied on the substrate W may be volatilized, but is not limited thereto.

The developing module 402 may perform the process of developing a pattern on the substrate W after the exposure process. The developing module 402 may include a second bake unit 720, and the second bake unit 720 may include a cooling member and the substrate processing apparatus 800. The substrate processing apparatus 800 of the second bake unit 720 may heat the substrate W to a preset temperature such that the surface properties of the substrate W may change, before the developing process. A description of the substrate processing apparatus 800 of the second bake unit 720 is substantially the same as that of the substrate processing apparatus 800 of the first bake unit 710, and is not duplicated here again.

However, embodiments of the present inventive concept are not limited thereto, and the substrate processing facility 1 may further include a second buffer module, a pre—and post-exposure processing module, and an interface module. For example, second buffer module, pre- and post-exposure processing module, and interface module may be sequentially disposed in a first side of the coating and developing module 400.

A substrate processing apparatus 800 according to an embodiment may refer to the substrate processing apparatus 800 of the first bake unit 710 and/or the substrate processing apparatus 800 of the second bake unit 720. That is, a substrate processing apparatus 800 according to an embodiment may perform a heat treatment process (e.g., a heating process) with respect to the substrate W after the process of applying the photoresist with respect to the substrate W, or may perform a heat treatment process (e.g., a heating process) before the process of developing a pattern on the substrate W.

Hereinafter, a substrate processing apparatus 800 for heat processing the substrate W according to an embodiment will be described.

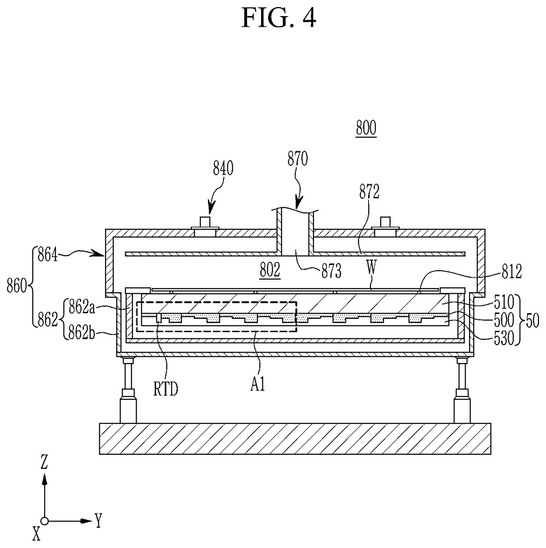

FIG. 4 is a cross-sectional view showing a substrate processing apparatus according to an embodiment. The substrate processing apparatus 800 of FIG. 4 may be a substrate processing apparatus 800 that performs a heat treatment process in the first bake unit 710 and/or the second bake unit 720 of FIG. 3.

A substrate processing apparatus 800 according to an embodiment may include a housing 860, a substrate supporting member 50, and a temperature sensor RTD.

The housing 860 may provide a processing space 802 in which a heat treatment process of the substrate W is performed. The housing 860 may include a lower body 862, and an upper body 864.

The lower body 862 may have a cylindrical shape with an open top. A plate 510 and a heating plate 500 may be disposed in the lower body 862. The lower body 862 may include double thermal insulation covers 862a and 862b to prevent devices located around the plate 510 from being thermally deformed. The double thermal insulation covers 862a and 862b may minimize exposure of peripheral devices of the plate 510 to high-temperature heat generated from the heating plate 500. The double thermal insulation covers 862a and 862b may include a primary thermal insulation cover 862a and a secondary thermal insulation cover 862b. The primary thermal insulation cover 862a and the secondary thermal insulation cover 862b may be disposed spaced apart from each other, as illustrated.

The upper body 864 may have a cylindrical shape having an open bottom. The upper body 864 may be disposed in an upper portion of the lower body 862. The upper body 864 may have a larger diameter than the lower body 862.

The upper body 864 may be combined with the lower body 862 to form the processing space 802 therein. The upper body 864 may move in a vertical direction. Accordingly, the upper body 864 may be spaced apart from the lower body 862 or may contact the lower body 862.

Although not shown, the housing 860 may include sealing members to prevent external air from entering the processing space. For example, the sealing member may seal a gap between the lower body 862 and the upper body 864.

A substrate processing apparatus 800 according to an embodiment may further include an exhaust unit 870 and a gas supply unit 840.

The exhaust unit 870 may be disposed to pass through the upper body 864. The exhaust unit 870 may exhaust the processing space. The exhaust unit 870 may include an exhaust pipe 873 and a counter plate 872. The exhaust pipe 873 may have a tubular shape with both ends open. The exhaust pipe 873 may pass through the upper body 864 and be fixed to the upper body 864. Gas existing in the processing space 802 may be exhausted through the exhaust pipe 873. The counter plate 872 may guide a flow direction of gas introduced into the processing space 802. The counter plate 872 may be disposed to face the plate 510. The gas supply unit 840 may be disposed to pass through the upper body 864. The gas supply unit 840 may supply gas into the processing space 802.

A substrate supporting member according to an embodiment 50 may include the plate 510, the heating plate 500, and an insulation layer 530.

The plate 510 may be disposed within the processing space 802. The plate 510 may have a circular plate shape. An upper surface of the plate 510 may be provided as a support region on which the substrate W is placed

A substrate supporting member according to an embodiment 50 may further include a thermal diffusion member 812. The thermal diffusion member 812 may be disposed on the upper surface of the plate 510. The thermal diffusion member 812 may be disposed apart from each other along a circumferential direction of the plate 510. The thermal diffusion member 812 may have the same interval. When the substrate W is provided in the substrate processing apparatus 800, the substrate W may be placed on an upper surface of the thermal diffusion member 812. The thermal diffusion member 812 may include a material having a thermal conductivity similar to that of air. Accordingly, when the substrate W is provided in the substrate processing apparatus 800, a gap may exist between the substrate W and the plate 510 due to the thermal diffusion member 812. Accordingly, heat from the heated plate 510 may be transferred to the substrate W through the thermal diffusion member 812 and air present in the gap. Since the thermal diffusion member 812 has a thermal conductivity similar to that of air, the amount of heat transferred to the substrate W through the thermal diffusion member 812 and the amount of heat transferred through a gap between the substrate W and the plate 510 may be similar to each other.

A plurality of lift pins (not shown) may be disposed on the upper surface of the plate 510 of a substrate processing apparatus 800 according to an embodiment. For example, three lift pins may be disposed on the upper surface of the plate 510, but is not limited thereto. For example, each lift pin may be disposed apart from each other along the circumferential direction of the plate 510. Each lift pin may have the same interval with each other. The lift pins may transport the substrate W in the vertical direction (e.g., the third direction (Z direction)).

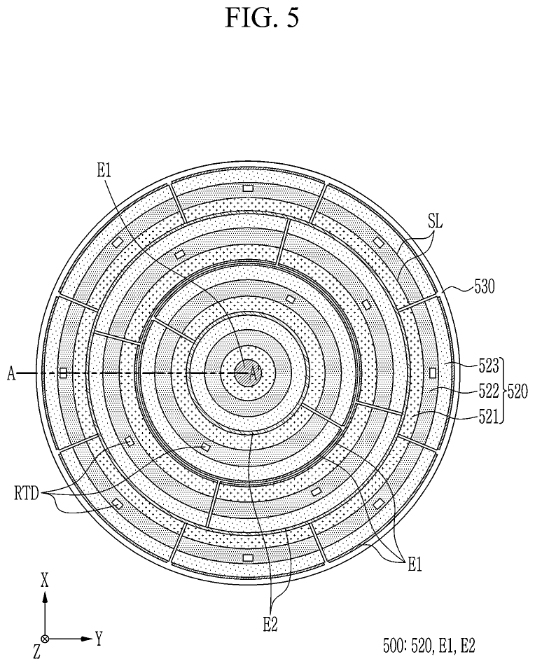

Hereinafter, a heating plate 500 according to an embodiment will be described with further reference to FIGS. 5 to 8.

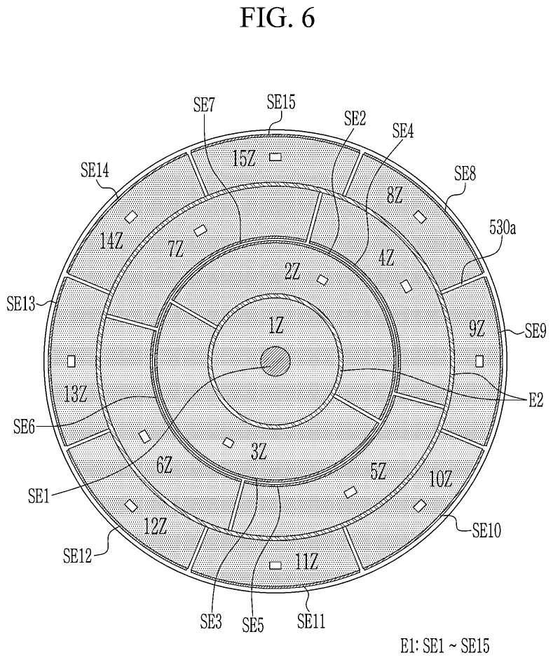

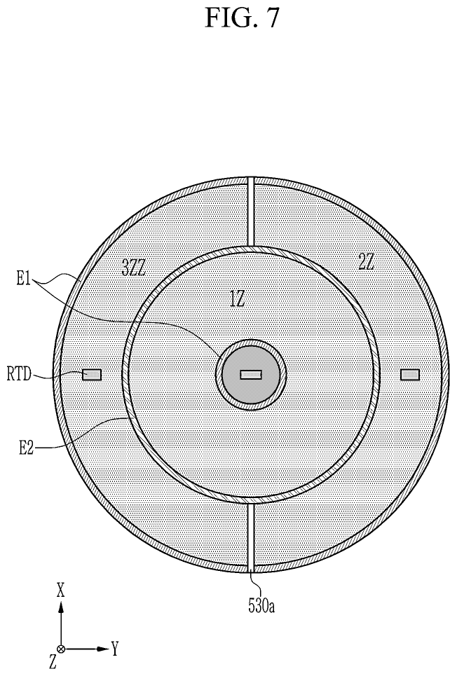

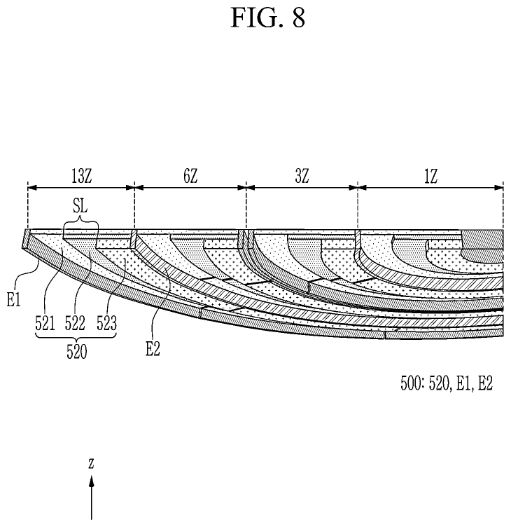

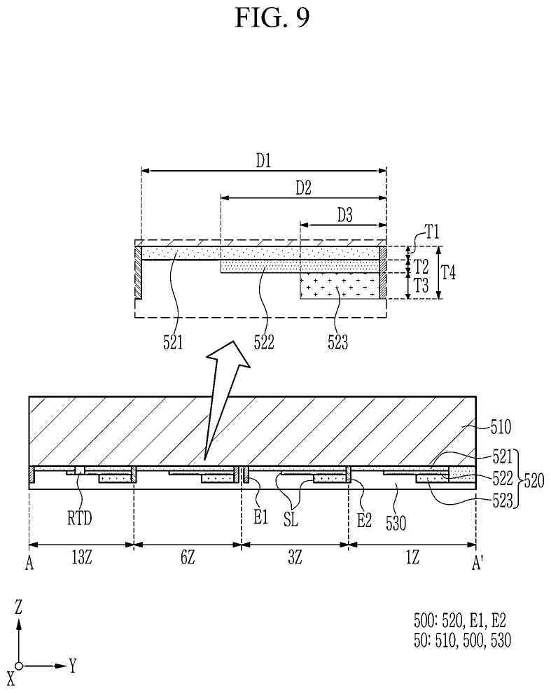

FIG. 5 is a bottom view showing a substrate supporting member of a substrate processing apparatus according to an embodiment. FIG. 6 is a bottom view showing a plurality of heating zones of a heating plate according to an embodiment. FIG. 7 is a bottom view showing a plurality of heating zones of a heating plate according to another embodiment. FIG. 8 is a perspective view showing a heating plate according to an embodiment. FIG. 9 is a cross-sectional view showing a substrate supporting member of a substrate processing apparatus according to an embodiment and corresponding to line A-A′ of FIG. 5.

The heating plate 500 may be disposed on a lower surface of the plate 510. The heating plate 500 may heat the substrate W placed on the plate 510 to a preset temperature.

Referring further to FIG. 5 and FIG. 6, a heating plate according to an embodiment 500 may include at least one heating zone. For example, the heating plate 500 may be divided into a plurality of heating zones 1Z to 15Z, as shown in FIG. 6. The plurality of heating zones 1Z to 15Z may be positioned on the same plane (i.e., are co-planar). The plurality of heating zones 1Z to 15Z may be a region in which the substrate supporting member 50 is heated.

Specifically, the plurality of heating zones 1Z to 15Z are partitioned by a plurality of lines extending radially from the center of the plate 510 and a plurality of circles spaced apart from each other in a direction in which the diameter increases toward the outside along the radial lines (i.e., concentric circles). In addition, in an embodiment, the plurality of heating zones 1Z to 15Z are arranged such that the number of outer partitions is greater than the number of inner partitions, and accordingly, the number of heating zones in the same circumferential direction increases from the center to the outside, but are not limited thereto.

In other words, the plurality of heating zones 1Z to 15Z may extend along the circumferential direction of the plate 510. The plurality of heating zones 1Z to 15Z may be arranged along the circumferential direction of the plate 510. For example, the first heating zone 1Z is located at the very center of the heating plate 500, and the second and third heating zones 2Z and 3Z may be positioned to surround the first heating zone 1Z. The second and third heating zones 2Z and 3Z may be arranged along the circumferential direction of the plate 510 (i.e., the second and third heating zones 2Z and 3Z are circumferentially adjacent each other and extend circumferentially around the first zone 1Z). In addition, the fourth to seventh heating zones 4Z to 7Z may be positioned to surround the second and third heating zones 2Z and 3Z. The fourth to seventh heating zones 4Z to 7Z may be arranged along the circumferential direction of the plate 510 (i.e., the fourth to seventh heating zones 4Z to 7Z are circumferentially adjacent each other and extend circumferentially around the second and third heating zones 2Z and 3Z). In addition, the eighth to fifteenth heating zones 8Z to 15Z may be positioned to surround the fourth to seventh heating zones 4Z to 7Z. The eighth to fifteenth heating zones 8Z to 15Z may be arranged along the circumferential direction of the plate 510 (i.e., the eighth to fifteenth heating zones 8Z to 15Z are circumferentially adjacent each other and extend circumferentially around the fourth to seventh heating zones 4Z to 7Z).

Here, the circumferential direction may be a circumferential direction of an imaginary circle perpendicular to a center axis direction of the plate 510. Hereinafter, for convenience of description, the circumferential direction of an imaginary circle perpendicular to the center axis direction of the plate 510 will be referred to as a circumferential direction (i.e., the circumference of the imaginary circle defines the “circumferential direction”).

The plurality of heating zones 1Z to 15Z may be spaced apart from each other to prevent mutual thermal interference. For example, the plurality of heating zones 1Z to 15Z arranged along the circumferential direction may be disposed spaced apart from each other (i.e., the plurality of heating zones 1Z to 5Z are in circumferentially adjacent, spaced apart relationship). For example, the second and third heating zones 2Z and 3Z, the fourth to seventh heating zones 4Z to 7Z, and the eighth to fifteenth heating zones 8Z to 15Z may be disposed spaced apart from each other (i.e., the second and third heating zones 2Z and 3Z, the fourth to seventh heating zones 4Z to 7Z, and the eighth to fifteenth heating zones 8Z to 15Z are radially spaced apart from each other, as illustrated). An isolation insulation layer 530 may be disposed between the plurality of heating zones 1Z to 15Z arranged along the circumferential direction. Here, the isolation insulation layer 530 may be a part of the insulation layer 530, but is not limited thereto.

In FIG. 6, as an example, the plurality of heating zones 1Z to 15Z are disposed in four radially spaced apart layers (i.e., 1Z, 2Z to 3Z, 4Z to 7Z, 8Z to 15Z), but are not limited thereto. For example, plurality of heating zones may also be disposed in three or less radially spaced apart layers. For example, as shown in FIG. 7, the heating plate 500 may include three heating zones. The first heating zone 1Z is concentrically surrounded by the second and third heating zones 2Z, 3Z, as illustrated. Alternatively, the heating zones may include five or more heating zones. In addition, the plurality of heating zones 1Z to 15Z are shown to be divided into fifteen, but are not limited thereto. For example, the plurality of heating zones 1Z to 15Z may be sixteen or more. Alternatively, the plurality of heating zones 1Z to 15Z may be fourteen or less.

In an embodiment, a plurality of heating members 520 may be disposed in each of the plurality of heating zones 1Z to 15Z. The plurality of heating zones 1Z to 15Z may be independently temperature controlled through each of the plurality of heating members 520.

A heating plate according to an embodiment 500 may include the plurality of heating members 520, a first electrode E1, and a second electrode E2.

The plurality of heating members 520 may be disposed on the lower surface of the plate 510. The plurality of heating members 520 may be disposed in each of the plurality of heating zones 1Z to 15Z. A heating member may be disposed to correspond to each of the plurality of heating zones 1Z to 15Z. That is, one heating member 520 may be disposed in one heating zone. For example, as shown in FIG. 5, the plurality of heating members 520 may be disposed in each of the plurality of heating zones 1Z to 15Z along an extension direction of the plurality of heating zones 1Z to 15Z. That is, the plurality of heating members 520 may extend along the circumferential direction of the plate 510 (i.e., the heating members 520 have an arcuate or curved configuration that matches the arcuate or curved configuration of the respective heating sones 1Z to 15Z). The plurality of heating members 520 may be positioned between the first electrode E1 and the second electrode E2 to be described later. For example, the plurality of heating members 520 may extended along the circumferential direction of the plate 510 between the first electrode E1 and the second electrode E2.

In an embodiment, the plurality of heating members 520 may generate heat by electrical signals. For example, the plurality of heating members 520 are connected to the first electrode E1 and the second electrode E2, and may generate heat by electrical signals applied from the first electrode E1 and the second electrode E2. In each of the plurality of heating zones 1Z to 15Z, the plurality of heating members 520 may be a planar heating element extending along the circumferential direction of the plate 510.

Each of the plurality of heating members 520 may include a stepped portion SL (i.e., a stair-step configuration) whose thickness in the third direction (Z direction) decreases as the distance from the center of the plate 510 increases, as illustrated. For example, as shown in FIG. 8 and FIG. 9, in each of the first heating zone 1Z, the third heating zone 3Z, a sixth heating zone 6Z, and a thirteenth heating zone 13Z, the plurality of heating members 520 may include a stepped portion (i.e., each have a stair-step configuration) whose thickness in the third direction (Z direction) decreases as the distance from the center of the plate 510 increases.

In an embodiment, since the plurality of heating members 520 extends along the circumferential direction of the plate 510, in a plan view, the length of an inner side surface of the plurality of heating members 520 may be shorter than the length of an outer side surface. Accordingly, in a plan view, an area of the plurality of heating members 520 may increase toward an outer side of the plate 510, and accordingly, the sheet resistance of the plurality of heating members 520 may decrease. Meanwhile, each of the plurality of heating members 520 according to an embodiment may include a stepped portion SL whose thickness in the third direction (Z direction) decreases as the distance from the center of the plate 510 increases. Accordingly, even if the sheet resistance of the plurality of heating members 520 increases toward the outer side of the plate 510, the resistance value according to the radial direction of the plate 510 of the plurality of heating members 520 may be maintained constant. Therefore, the temperature deviation of the plate 510 due to heating of the plurality of heating members 520 may decrease.

In an embodiment, in at least some of the plurality of heating zones 1Z to 15Z, the plurality of heating members 520 may include a stepped portion SL whose thickness in the third direction (Z direction) increases from the second electrode E2 toward the first electrode E1. For example, in the first heating zone 1Z and the sixth heating zone 6Z, the plurality of heating members 520 may include a stepped portion SL whose thickness in the third direction (Z direction) increases from the second electrode E2 toward the first electrode E1. In addition, in the remaining heating zone of the plurality of heating zones 1Z to 15Z, the plurality of heating members 520 may include a stepped portion SL whose thickness in the third direction (Z direction) decreases from the second electrode E2 toward the first electrode E1. For example, in the third heating zone 3Z and the thirteenth heating zone 13Z, the plurality of heating members 520 may include a stepped portion SL whose thickness in the third direction (Z direction) decreases from the second electrode E2 toward the first electrode E1.

In FIG. 8 and FIG. 9, as an example, the first heating zone 1Z, the third heating zone 3Z, the sixth heating zone 6Z, and the thirteenth heating zone 13Z have been described, but in each of the plurality of heating zones 1Z to 15Z, the plurality of heating members 520 may include a stepped portion SL whose thickness in the third direction (Z direction) decreases as the distance from the center of the plate 510 increases.

The plurality of heating members 520 may include a carbon nano compound. For example, the plurality of heating members 520 may include graphene, carbon nanotubes (CNT, (for example, single-walled carbon nanotubes, double-walled carbon nanotubes, multi-walled carbon nanotubes, rope carbon nanotubes, and the like)), and carbon balls, and the like, but is not limited thereto.

Referring further to FIG. 8 and FIG. 9, the plurality of heating members 520 according to an embodiment may include a first heating member 521, a second heating member 522, and a third heating member 523 that are sequentially disposed on the lower surface of the plate 510, as illustrated.

The first heating member 521 may be disposed on the lower surface of the plate 510. The first heating member 521 may directly contact the lower surface of the plate 510. The second heating member 522 may be disposed on a lower surface of the first heating member 521. The second heating member 522 may directly contact the lower surface of the first heating member 521. The third heating member 523 may be disposed on a lower surface of the second heating member 522. The third heating member 523 may directly contact the lower surface of the second heating member 522.

A first side surface of the first heating member 521, a first side surface of the second heating member 522, and a first side surface of the third heating member 523 may be aligned on the same boundary (i.e., the first side surface of the first heating member 521, the first side surface of the second heating member 522, and the first side surface of the third heating member 523 are aligned with each other, as illustrated). For example, in the case of the first heating zone 1Z and the sixth heating zone 6Z of FIG. 8 and FIG. 9, the first side surface of the first heating member 521, the first side surface of the second heating member 522, and first side surface of the third heating member 523 may contact the first electrode E1, as illustrated. The first side surface of the first heating member 521, the first side surface of the second heating member 522, and the first side surface of the third heating member 523 may be aligned on the same boundary (i.e., the first side surface of the first heating member 521, the first side surface of the second heating member 522, and the first side surface of the third heating member 523 are aligned with each other, as illustrated). As another example, in the case of the third heating zone 3Z and the thirteenth heating zone 13Z of FIG. 8 and FIG. 9, the first side surface of the first heating member 521, the first side surface of the second heating member 522, and first side surface of the third heating member 523 may contact the second electrode E2, as illustrated. The first side surface of the first heating member 521, the first side surface of the second heating member 522, and the first side surface of the third heating member 523 may be aligned on the same boundary (i.e., the first side surface of the first heating member 521, the first side surface of the second heating member 522, and the first side surface of the third heating member 523 are aligned with each other, as illustrated).

In addition, the first heating member 521 to the third heating member 523 may have different widths. For example, a first width D1 of the plate 510 of the first heating member 521 according to the radial direction may be greater than a second width D2 according to the radial direction of the plate 510 of the second heating member 522. In addition, the second width D2 of the plate 510 of the second heating member 522 according to the radial direction may be greater than a third width D3 of the third heating member 523 according to the radial direction of the plate 510. Accordingly, the stepped portion ST may be provided at an end of the second and third heating members 522, 523, and the plurality of heating members 520 may have a stepped shape.

Thicknesses of the first heating member 521 to the third heating member 523 according to in the third direction (Z direction) may be different. For example, a first thickness T1 of the first heating member 521 according the third direction (Z to direction) may be smaller than a third thickness T3 of the third heating member 523 in the third direction (Z direction). A second thickness T2 of the second heating member 522 in the third direction (Z direction) may be smaller than the third thickness T3 of the third heating member 523 in the third direction (Z direction). For example, the first thickness T1 of the first heating member 521 in the third direction may be 5 nm to 15 nm. The second thickness T2 of the second heating member 522 in the third direction may be 5 nm to 15 nm. The third thickness T3 of the third heating member 523 in the third direction may be 15 nm to 25 nm. However, it is not limited thereto, and the thickness of the first heating member 521 to the third heating member 523 may be varied such that the plurality of heating members 520 may have the same resistance value according to the radial direction of the plate 510.

As an example, a thickness T4 of the first to third heating members 523 in the third direction (Z direction) may be 1/25 or less of a thickness of the plate 510 in the third direction (Z direction). For example, the thickness T4 of the first to third heating member 523 in the third direction (Z direction) may be 25 nm to 40 nm. A thickness of the plate 510 in the third direction (Z direction) may be 1 mm to 2 mm. Since the plurality of heating members 520 according to an embodiment act as planar heating elements, thickness of the third heating member 523 according to first to the third direction (Z direction) may be decreased. In addition, as described above, since the temperature deviation of the plate 510 due to heating of the plurality of heating members 520 is decreased, a thickness of the plate 510 in the third direction (Z direction) may be decreased.

At least a portion of the first heating member 521 to the third heating member 523 may include a carbon nano compound. For example, at least a portion of the first heating member 521 to the third heating member 523 may include graphene, carbon nanotubes (CNT, (for example, single-walled carbon nanotubes, double-walled carbon nanotubes, multi-walled carbon nanotubes, rope carbon nanotubes, and the like)), and carbon balls, and the like, but is not limited thereto. At least a portion of the first heating member 521 to the third heating member 523 may include the same material.

The first electrode E1 and the second electrode E2 may be disposed on both side surfaces of the plurality of heating members 520. That is, the plurality of heating members 520 may be disposed between the first electrode E1 and the second electrode E2. The first electrode E1 and the second electrode E2 may be disposed on the same plane. For example, the first electrode E1 and the second electrode E2 may be disposed on the lower surface of the plate 510, but is not limited thereto.

In an embodiment, the first electrode E1 and the second electrode E2 may be disposed spaced apart from each other. For example, the first electrode E1 and the second electrode E2 may be alternately disposed along the radial direction of the plate 510.

In addition, the first electrode E1 and the second electrode E2 may extend along the circumferential direction of the plate 510. Specifically, at least a portion of the first electrode E1 may be arranged along the circumferential direction of the plate 510. At least a portion of the first electrode E1 may be disposed in the central portion of the plate 510. In addition, the second electrode E2 may be disposed between the first electrodes E1. For example, the second electrode E2 may extend along the circumferential direction of the plate 510 between the first electrodes E1. The second electrode E2 may have a ring shape extending in the circumferential direction of the plate 510.

In at least some of the plurality of heating zones 1Z to 15Z, the first electrode E1 may be disposed on the inner side surface of the plurality of heating members 520. The inner side surface of the heating member 520 may be the side surface of the heating member 520 facing the center of the plate 510. For example, in the first heating zone 1Z and the sixth heating zone 6Z, the first electrode E1 may conformally extend along the inner side surface of the plurality of heating members 520. That is, the first electrode E1 may be arranged along the circumferential direction of the plate 510. The first electrode E1 may be connected to the inner side surface of the plurality of heating members 520. In addition, in the first heating zone 1Z and the sixth heating zone 6Z, the second electrode E2 may be disposed on an outer side surface of the plurality of heating members 520. Here, an outer side surface of the heating member 520 may be the side surface of the heating member 520 facing an edge of the plate 510. The second electrode E2 may conformally extend along the outer side surface of the plurality of heating members 520. That is, the second electrode E2 be may disposed along the circumferential direction of the plate 510. The second electrode E2 may be connected to the outer side surface of the plurality of heating members 520.

In addition, in the remaining heating zone of the plurality of heating zones 1Z to 15Z, the first electrode E1 may be disposed on the outer side surface of the plurality of heating members 520. For example, in the third heating zone 3Z and the thirteenth heating zone 13Z, the first electrode E1 may conformally extend along the outer side surface of the plurality of heating members 520. That is, the first electrode E1 may be arranged along the circumferential direction of the plate 510. The first electrode E1 may be connected to the outer side surface of the plurality of heating members 520. In addition, in the third heating zone 3Z and the thirteenth heating zone 13Z, the second electrode E2 may be disposed on the inner side surface of the plurality of heating members 520. The second electrode E2 may conformally extend along the inner side surface of the plurality of heating members 520. That is, the second electrode E2 may be arranged along the circumferential direction of the plate 510. The second electrode E2 may be connected to the inner side surface of the plurality of heating members 520.

In an embodiment, the first electrode E1 may include sub-electrodes SE1 to SE15 (FIG. 6). Each of the sub-electrodes SE1 to SE15 may correspond to the plurality of heating members 520. For example, as shown in FIG. 5 and FIG. 6, when fifteen heating members 520 are provided, the first electrode E1 may include the fifteen sub-electrodes SE1 to SE15.

The sub-electrodes SE1 to SE15 may be disposed apart from each other along the circumferential direction of the plate 510. For example, the sub-electrodes SE1 to SE15 may be disposed on a first side surface of the plurality of heating members 520 arranged apart from each other along the circumferential direction. For example, second and third sub-electrodes SE2 and SE3 may be disposed apart from each other along the circumferential direction of the plate 510. Fourth to seventh sub-electrodes SE4 to SE7 may be disposed apart from each other along the circumferential direction of the plate 510. Eighth to fifteenth sub-electrodes SE8 to SE15 may be disposed apart from each other along the circumferential direction of the plate 510. Accordingly, the sub-electrodes SE1 to SE15 may be connected to the plurality of heating members 520, respectively. Meanwhile, the second electrode E2 may be connected to a plurality of plurality of heating members 520 arranged along the circumferential direction. Accordingly, each of the plurality of heating members 520 of the plurality of heating zones 1Z to 15Z may be connected to different sub-electrodes, and may share the second electrode E2.

As an example, as shown in FIG. 5 and FIG. 6, the plurality of heating members 520 may be respectively connected to a second sub-electrode SE2 and the second electrode E2 in a second heating zone 2Z, and respectively connected to a third sub-electrode SE3 and the second electrode E2 in the third heating zone 3Z. In an embodiment, even if the plurality of heating members 520 shares the second electrode E2 in each of the plurality of heating zones 1Z to 15Z, since they are connected to the different sub-electrodes SE1 to SE15 respectively, each of the plurality of heating members 520 of the plurality of heating zones 1Z to 15Z may be independently heated.

The first electrode E1 and the second electrode E2 may include a conductive material. The first electrode E1 and the second electrode E2 may include, for example, at least one of copper, silver, gold, and aluminum.

In an embodiment, the isolation insulation layer 530 may be disposed between the first electrodes E1 arranged along the circumferential direction. Here, the isolation insulation layer 530 may be a part of the insulation layer 530, but is not limited thereto.

The insulation layer 530 may be disposed on a lower surface of the plurality of heating members 520. The insulation layer 530 may cover the lower surface of the plate 510, the lower surface of the plurality of heating members 520, the first electrode E1, and a lower surface of the second electrode E2. The insulation layer 530 may be disposed between the plurality of heating members 520 and between the first electrodes E1 arranged along the circumferential direction of the plate. The insulation layer 530 may include various insulating materials. The insulation layer 530 may include, for example, silicon oxide, silicon nitride, silicon oxycarbide, silicon carbonitride, and carbonized compound, but is not limited thereto.

Referring back to FIG. 4, the temperature sensor RTD may measure the temperature of the plate 510. The temperature sensor RTD may be positioned on the lower surface of the plate 510, but is not limited thereto, and the temperature sensor RTD may be positioned inside the plate 510. In addition, the temperature sensor RTD may be positioned in each of the plurality of heating zones 1Z to 15Z.

In an embodiment, the temperature sensor RTD has been described as measuring the temperature of the plate 510, but is not limited thereto. For example, the temperature sensor RTD may measure the temperature of heating members 520. The temperature sensor RTD may measure the temperature of the plurality of heating members 520 by using current and voltage flowing through the plurality of heating members 520.

The plurality of heating members 520 of a substrate processing apparatus 800 according to an embodiment may be a planar heating element extending along the circumferential direction of the plate 510. Accordingly, the area of the plurality of heating members 520 contacting the plate 510 may be increased compared to the case where the plurality of heating members 520 are linear heating elements. Accordingly, when it is desired to change the plate 510 to a preset temperature, the time required for the plate 510 in contact with the plurality of heating members 520 according to an embodiment to change to the preset temperature may be shortened.

In addition, the plurality of heating members 520 according to an embodiment are planar heating elements extending along the circumferential direction of the plate 510, in a plan view, the length of the inner side surface of the plurality of heating members 520 may be shorter than the length of an outer side surface. That is, in a plan view, the area of the plurality of heating members 520 may increase toward the outer side of the plate 510, and accordingly, the sheet resistance of the plurality of heating members 520 may decrease. Meanwhile, each of the plurality of heating members 520 according to an embodiment may include a stepped portion SL whose thickness in the third direction (Z direction) decreases as the distance from the center of the plate 510 increases. Accordingly, even if the sheet resistance of the plurality of heating members 520 increases toward the outer side of the plate 510, a resistance value of the plurality of heating members 520 may be maintained constant along the radial direction of the plate 510. Therefore, the temperature deviation of a heating support member 50 due to heating of the plurality of heating members 520 may be decreased, and reliability of the substrate processing apparatus 800 may be improved.

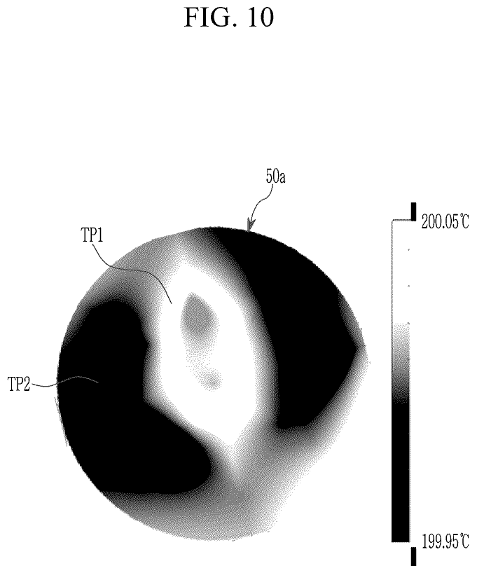

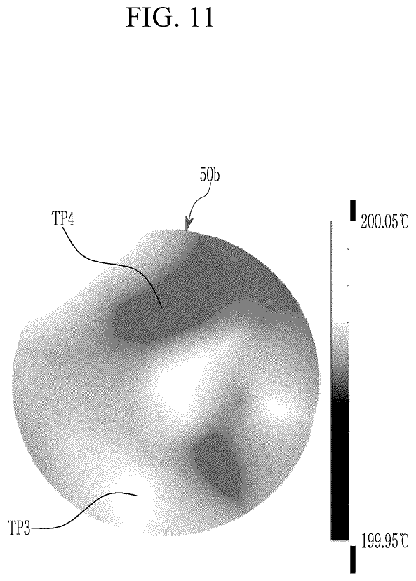

Hereinafter, a temperature deviation of a heating member according to an embodiment will be described with reference to FIG. 10 and FIG. 11.

FIG. 10 is a drawing for a Comparative Example where the heating member is a linear heating element. FIG. 11 is a drawing for an example of a heating member including a planar heating element according to an embodiment. FIG. 10 is a drawing showing a temperature distribution of a substrate supporting member according to Comparative Example. FIG. 11 is a drawing showing a temperature distribution of a substrate supporting member according to an embodiment.

In the process of applying current to the plurality of heating members 520, the temperature distribution of the plate 510 according to the heating of the plurality of heating members 520 is simulated.

Referring to FIG. 10 and FIG. 11, when the plurality of heating members 520 of the Comparative Example are linear heating elements, it may be confirmed that the temperature deviation of a substrate supporting member 50a due to heating of the plurality of heating members 520 is approximately 0.1° C. Here, the temperature deviation may mean a difference between the temperature the highest temperature portion TP1 and the temperature of the lowest temperature portion TP2, of the substrate supporting member 50a of the Comparative Example.

On the other hand, when the plurality of heating members 520 according to an embodiment are planar heating elements, it may be confirmed that the temperature deviation of a substrate supporting member 50b due to heating of the plurality of heating members 520 is approximately 0.05° C. That is, when the plurality of heating members 520 are planar heating elements, it may be confirmed that, compared to the plurality of heating members 520, which are linear heating elements, of the Comparative Example, the temperature deviation of the substrate supporting member 50b decreases. Here, the temperature deviation may mean a difference between the temperature the highest temperature portion TP3 and the temperature of the lowest temperature portion TP4, of a substrate supporting member according to an embodiment 50b.

In an embodiment, when the plurality of heating members 520 are planar heating elements, since the plurality of heating members 520 extend along the circumferential direction of the plate 510, in a plan view, the length of the inner side surface of the plurality of heating members 520 may be shorter than the length of an outer side surface. Accordingly, in a plan view, the area of the plurality of heating members 520 may increase toward the outer side of the plate 510, and accordingly, the sheet resistance of the plurality of heating members 520 may decrease. Meanwhile, each of the plurality of heating members 520 according to an embodiment may include a stepped portion SL whose thickness in the third direction (Z direction) decreases as the distance from the center of the plate 510 increases.

Accordingly, even if the sheet resistance of the plurality of heating members 520 increases toward the outer side of the plate 510, the resistance value according to the radial direction of the plate 510 of the plurality of heating members 520 may be maintained constant. Therefore, the temperature deviation of the substrate supporting member 50 due to heating of the plurality of heating members 520 may decrease.

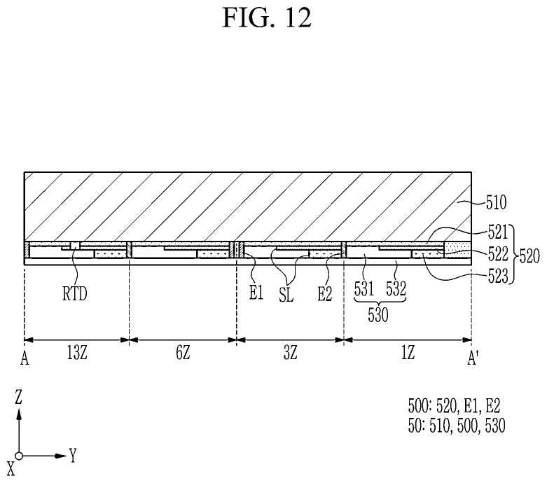

Hereinafter, a substrate processing apparatus according to another embodiment will be described with reference to FIG. 12 to FIG. 15.

FIG. 12 is a cross-sectional view showing a substrate supporting member according to another embodiment and corresponding to line A-A′ of FIG. 5.

Since the embodiment shown in FIG. 12 has substantially the same parts as the embodiment shown in FIG. 1 to FIG. 8, a description thereof will be omitted and differences will be mainly described. In the present embodiment, the arrangement of the insulation layer 530 is different from the previous embodiment, which will be described below.

Referring to FIG. 12, the insulation layer 530 of a substrate supporting member according to an embodiment 50 may include a first insulation layer 531 and a second insulation layer 532.

The first insulation layer 531 may be disposed on the lower surface of the plurality of heating members 520. The first insulation layer 531 may cover the lower surface of the plate 510, the lower surface of the plurality of heating members 520, the first electrode E1, and the lower surface of the second electrode E2. The first insulation layer 531 may be disposed between the plurality of heating members 520 and between the first electrodes E1 arranged along the circumferential direction of the plate. A lower surface of the first insulation layer 531 may be aligned on the same boundary as the lower surface of the plurality of heating members 520. That is, the lower surface of the first insulation layer 531 may be positioned at substantially the same level as the lower surface of the plurality of heating members 520.

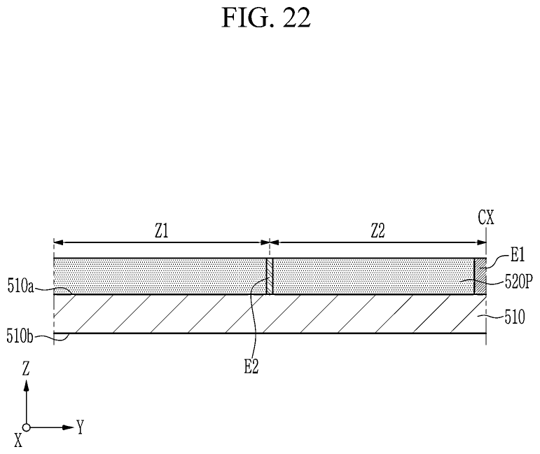

The first insulation layer 531 may include various insulating materials. The first insulation layer 531 may include, for example, a carbonized compound. In the process of forming the plurality of heating members 520 by using laser processing, in the first insulation layer 531, the heating member material layer (refer to ‘520P’ in FIG. 22) of the portion irradiated with a laser LL may be formed by in complete combustion. That is, the first insulation layer 531 may be a portion remaining after the heating member material layer (refer to ‘520P’ in FIG. 22) is patterned by using laser processing.

The second insulation layer 532 may be disposed on the lower surface of the first insulation layer 531. The second insulation layer 532 may completely cover the lower surface of the first insulation layer 531, but is not limited thereto. The second insulation layer 532 may include various insulating materials. The second insulation layer 532 may include, for example, silicon oxide, silicon nitride, silicon oxycarbide, and silicon carbonitride, and the like, but is not limited thereto.

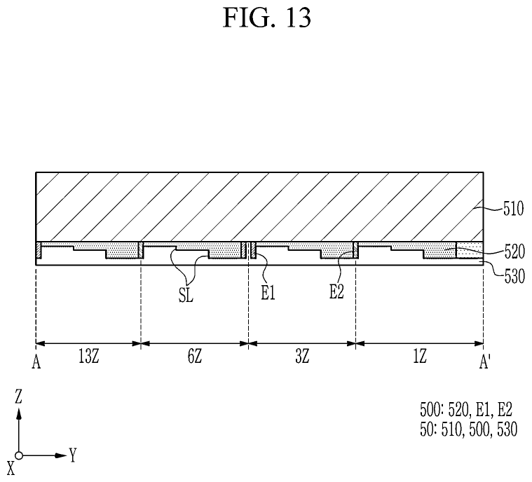

FIG. 13 is a cross-sectional view showing still a substrate supporting member according to another embodiment and corresponding to line A-A′ of FIG. 5.

Since the embodiment shown in FIG. 13 has substantially the same parts as the embodiment shown in FIG. 1 to FIG. 8, a description thereof will be omitted and differences will be mainly described. In the present embodiment, the configuration of the plurality of heating members 520 is different from the previous embodiment, which will be described below.

Referring to FIG. 13, the plurality of heating members 520 may be disposed on the lower surface of the plate 510. The plurality of heating members 520 may be disposed in each of the plurality of heating zones 1Z to 15Z along the extension direction of the plurality of heating zones 1Z to 15Z. That is, the plurality of heating members 520 may extend along the circumferential direction of the plate 510. The plurality of heating members 520 may be positioned between the first electrode E1 and the second electrode E2. For example, the plurality of heating members 520 may extend along the circumferential direction of the plate 510 between the first electrode E1 and the second electrode E2.

In an embodiment, in each of the plurality of heating zones 1Z to 15Z, a step may be provided at one end of the plurality of heating members 520. That is, in each of the plurality of heating zones 1Z to 15Z, the plurality of heating members 520 may include a stepped portion SL whose thickness in the third direction (Z direction) decreases as the distance from the center of the plate 510 increases.

The plurality of heating members 520 may include a single material. For example, the plurality of heating members 520 may include a carbon nano compound. Each part of the plurality of heating members 520 including the step may be integrally formed such that the boundary may not be visually recognized.

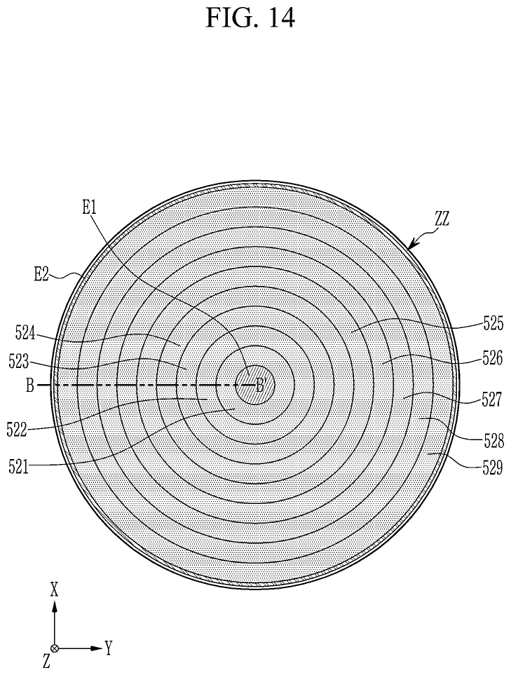

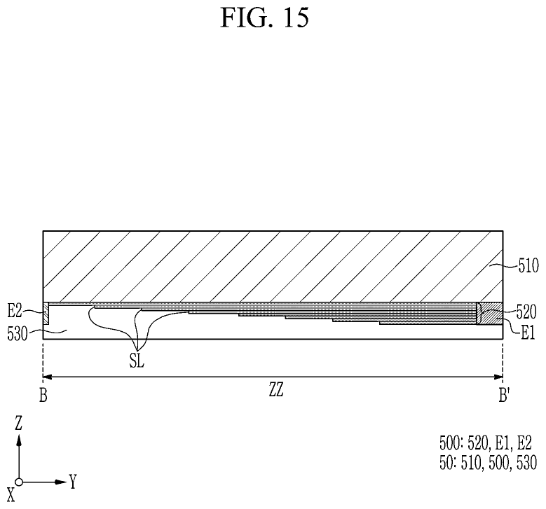

FIG. 14 is a bottom view showing a substrate supporting member of a substrate processing apparatus according to another embodiment. FIG. 15 is a cross-sectional view showing a substrate supporting member according to another embodiment and corresponding to line B-B′ of FIG. 14.

Since the embodiment shown in FIG. 14 and FIG. 15 has substantially the same parts as the embodiment shown in FIG. 1 to FIG. 8, a description thereof will be omitted and differences will be mainly described. In the present embodiment, the number and arrangement of the plurality of heating zones 1Z to 15Z is different from the previous embodiment, which will be described below.

Referring to FIG. 14 and FIG. 15, a heating plate according to an embodiment 500 may include one heating zone ZZ, and may include one heating member 520.

In an embodiment, the plurality of heating members 520 may have a ring shape extending in the circumferential direction of the plate. For example, first to ninth heating members 521 to 529 may have a ring shape extending in the circumferential direction of each plate. The heating member 520 may be a planar heating element extending along the circumferential direction of the plate 510 in the heating zone ZZ.

In an embodiment, the heating member 520 may include a stepped portion SL whose thickness in the third direction (Z direction) decreases as the distance from the center of the plate 510 increases.

In an embodiment, the first electrode E1 may be disposed in the central portion of the plate 510. The first electrode E1 may be disposed on an inner side surface of the first heating member 521. In addition, the second electrode E2 may extend along the circumference of the plate 510. The second electrode E2 may have a ring shape extending in the circumferential direction of the plate 510. The second electrode E2 may be disposed on the outer side surface of the plurality of heating members 520. The second electrode E2 may be conformally extended along an outer side surface of a plurality of heating members 520. The second electrode E2 may be connected to the outer side surface of the plurality of heating members 520. Accordingly, the plurality of heating members 520 may include a stepped portion SL whose thickness in the third direction (Z direction) increases from the second electrode E2 toward the first electrode E1.

FIG. 14 and FIG. 15 show that the heating plate 500 includes first to ninth heating members 521 to 529, but the number of the plurality of heating members 520 is not limited thereto. For example, the heating plate 500 may include a plurality of heating members 520 in a quantity of eight or less. Alternatively, the heating plate 500 may include a plurality of heating members 520 in a quantity of ten or more.

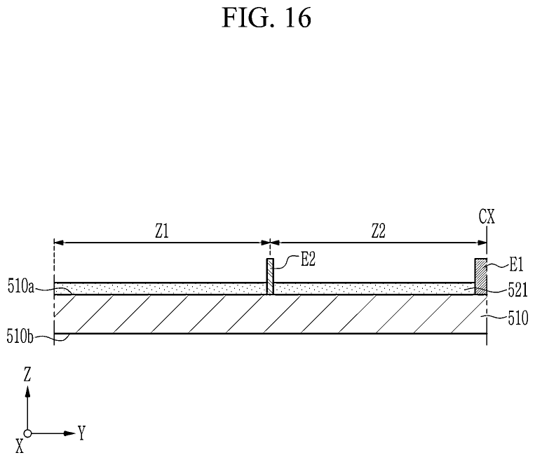

Hereinafter, a manufacturing method a heating plate of a substrate processing apparatus according to an embodiment will be described with reference to FIG. 16 to FIG. 21.

FIG. 16 to FIG. 21 are intermediate step drawings for explaining a manufacturing method of a substrate supporting member of a substrate processing apparatus according to an embodiment. For convenience of description, descriptions of overlapping contents with those described with reference to FIG. 1 to FIG. 8 may be omitted.

Referring to FIG. 16, first, the plate 510 is prepared. The plate 510 may include a second surface 510b and an opposing first surface 510a, as illustrated. In an embodiment, the first surface 510a of the plate 510 may be referred to as a lower surface. The second surface 510b of the plate 510 may be referred to as an upper surface.

The first electrode E1 and the second electrode E2 are formed on the first surface 510a of the plate 510. Specifically, the first electrode E1 may be formed in the central portion of the plate 510. It is illustrated that the first electrode E1 is only formed in the central portion of the plate 510, but it is not limited thereto, and the first electrode E1 described in FIG. 1 to FIG. 8 may be formed. The second electrode E2 may be formed to extend along the circumferential direction of the plate 510. Although it is illustrated that one second electrode E2 is formed, a plurality of second electrodes E2 may be formed on the first surface 510a of the plate 510.

The first electrode E1 may be disposed apart from the second electrode E2 along the radial direction of the plate 510. The first electrode E1 may be arranged along the circumferential direction of the plate 510. The first electrode E1 and the second electrode E2 may include a conductive material. The first electrode E1 and the second electrode E2 may include, for example, at least one of copper, silver, gold, and aluminum.

Subsequently, in each of the plurality of heating zones 1Z to 15Z, the first heating member 521 may be formed on the first surface 510a of the plate 510. The first heating member 521 may be formed between the first electrode E1 and the second electrode E2. In each of the plurality of heating zones 1Z to 15Z, the first heating member 521 may extend along the circumferential direction of the plate 510. The first heating member 521 may be deposited by using physical deposition (PVD) or chemical deposition (CVD). The drawings illustrate the first and second heating zones 1Z and 2Z, but embodiments of the present inventive concept are not limited thereto, and in each of the plurality of heating zones 1Z to 15Z, the first heating member 521 may be formed on the first surface 510a of the plate 510.

The first heating member 521 may include a carbon nano compound. For example, the first heating member 521 may include graphene, carbon nanotubes (CNT, (for example, single-walled carbon nanotubes, double-walled carbon nanotubes, multi-walled carbon nanotubes, rope carbon nanotubes, and the like)), and carbon balls, and the like, but is not limited thereto.

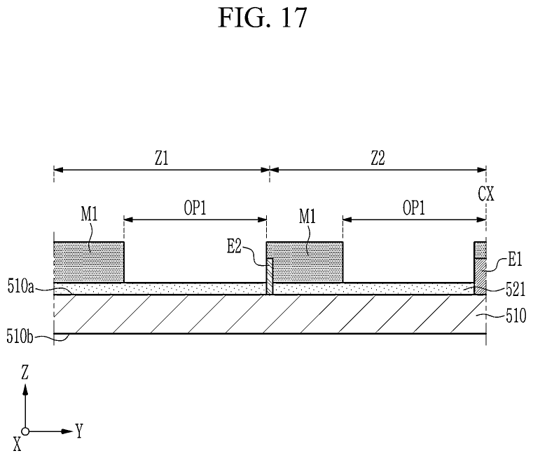

Referring to FIG. 17, a first mask pattern M1 including a first opening OP1 is formed on the first heating member 521. In each of the plurality of heating zones 1Z to 15Z, the first mask pattern M1 may be disposed away from the center axis CX of the plate 510. That is, in each of the plurality of heating zones 1Z to 15Z, the first opening OP1 may be disposed close to the center axis CX of the plate 510. The first opening OP1 may be formed to expose a portion of the first heating member 521. The first mask pattern M1 may be disposed on the first electrode E1 and the second electrode E2. The first mask pattern M1 may be, for example, a hard mask pattern, but is not limited thereto.

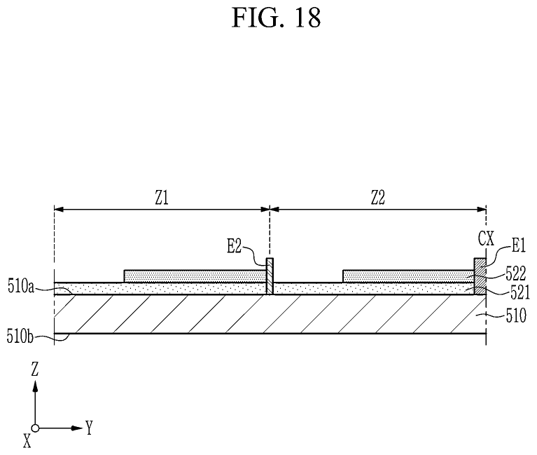

Referring to FIG. 18, the second heating member 522 may be formed on the first heating member 521 exposed by the first opening OP1. In each of the plurality of heating zones 1Z to 15Z, the second heating member 522 may extend along the circumferential direction of the plate 510. As the first mask pattern M1 partially overlaps the first heating member 521, a step may be formed at one end of the second heating member 522. The width of the plate 510 of the second heating member 522 according to the radial direction may be smaller than the width of the plate 510 of the first heating member 521.

The second heating member 522 may be deposited by using physical deposition (PVD) or chemical deposition (CVD). The second heating member 522 may include a carbon nano compound. For example, the second heating member 522 may include graphene, carbon nanotubes (CNT, (for example, single-walled carbon nanotubes, double-walled carbon nanotubes, multi-walled carbon nanotubes, rope carbon nanotubes, and the like)), and carbon balls, and the like, but is not limited thereto. Thereafter, the first mask pattern M1 may be removed.

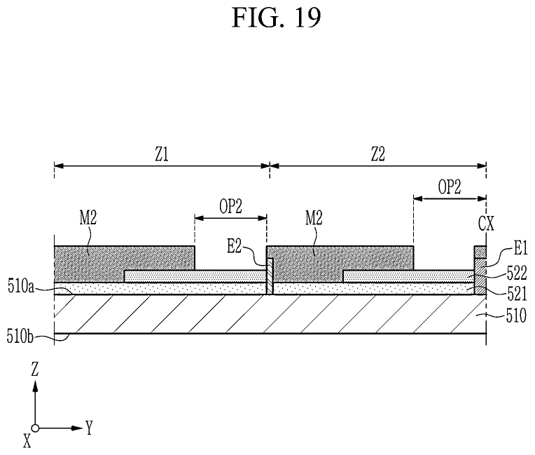

Referring to FIG. 19, a second mask pattern M2 including a second opening OP2 is formed on the first heating member 521 and the second heating member 522. In each of the plurality of heating zones 1Z to 15Z, the second mask pattern M2 may be disposed away from the center axis CX of the plate 510. That is, in each of the plurality of heating zones 1Z to 15Z, the second opening OP2 may be disposed close to the center axis CX of the plate 510. The second opening OP2 may be formed to expose a portion of the second heating member 522. The second mask pattern M2 may be disposed on the first electrode E1 and the second electrode E2. The second mask pattern M2 may be patterned through a photolithography process, but is not limited thereto.

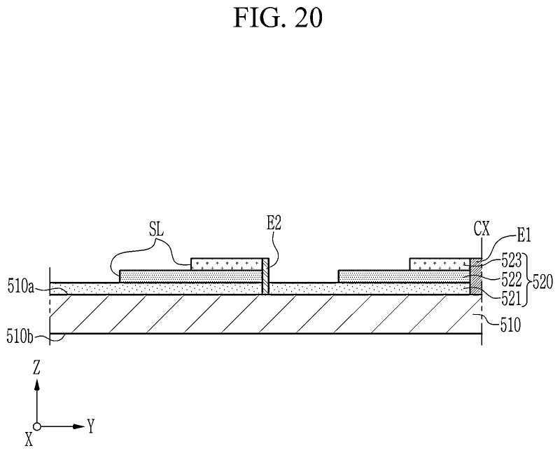

Referring to FIG. 20, the third heating member 523 is formed on the second heating member 522 exposed by the second opening OP2. In each of the plurality of heating zones 1Z to 15Z, the third heating member 523 may extend along the circumferential direction of the plate 510. As the second mask pattern M2 partially overlaps the second heating member 522, a step may be formed at one end of the third heating member 523. The width of the third heating member 523 according to the radial direction of the plate 510 may be smaller than the width of the plate 510 of the second heating member 522 according to the radial direction.

The third heating member 523 may be deposited by using physical deposition (PVD) or chemical deposition (CVD). The third heating member 523 may include a carbon nano compound. For example, the third heating member 523 may include graphene, carbon nanotubes (CNT, (for example, single-walled carbon nanotubes, double-walled carbon nanotubes, multi-walled carbon nanotubes, rope carbon nanotubes, and the like)), and carbon balls, and the like, but is not limited thereto. Thereafter, the second mask pattern M2 may be removed.

In an embodiment, as steps are formed at ends of the second and third heating members 522 and 523, in each of the plurality of heating zones 1Z to 15Z, the plurality of heating members 520 may include a stepped portion SL whose thickness in the third direction (Z direction) decreases as the distance from the center axis CX of the plate 510 increases.

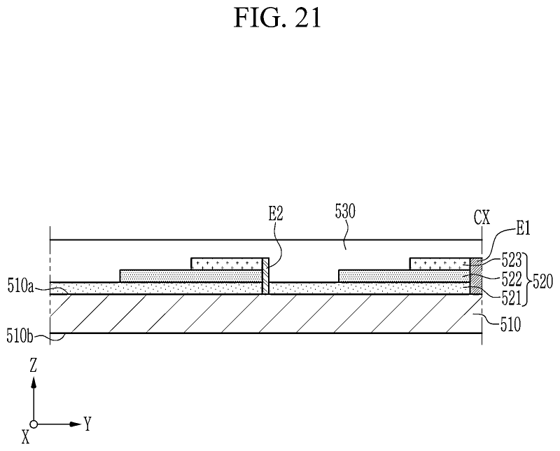

Referring to FIG. 21, the insulation layer 530 may be formed to cover the plurality of heating members 520, the first electrode E1 and the second electrode E2.

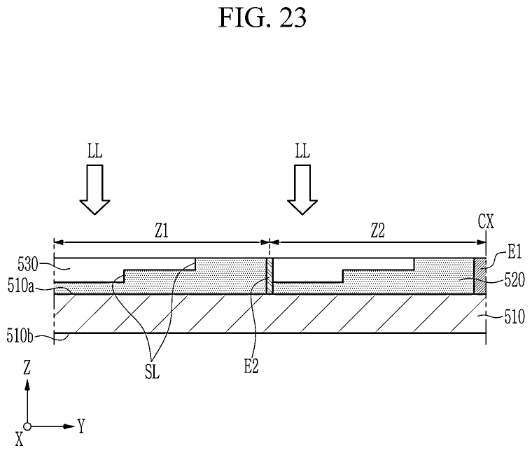

Hereinafter, a manufacturing method of a heating plate of a substrate processing apparatus according to another embodiment will be described with reference to FIG. 22 and FIG. 23.

FIG. 22 and FIG. 23 are intermediate step drawings for explaining a manufacturing method of a substrate supporting member of a substrate processing apparatus according to another embodiment.

Referring to FIG. 22, first, the plate 510 is prepared. The plate 510 may include a second surface 510b and an opposing first surface 510a, as illustrated. In an embodiment, the first surface 510a of the plate 510 may be referred to as a lower surface. The second surface 510b of the plate 510 may be referred to as an upper surface.

The first electrode E1 and the second electrode E2 are formed on the first surface 510a of the plate 510. Specifically, the first electrode E1 may be formed in the central portion of the plate 510. It is illustrated that the first electrode E1 is only formed in the central portion of the plate 510, but it is not limited thereto, and the first electrode E1 described in FIG. 1 to FIG. 8 may be formed. The second electrode E2 may be formed to extend along the circumferential direction of the plate 510. Although it is illustrated that one second electrode E2 is formed, a plurality of second electrodes E2 may be formed on the first surface 510a of the plate 510.

The first electrode E1 may be disposed apart from the second electrode E2 along the radial direction of the plate 510. The first electrode E1 may be arranged along the circumferential direction of the plate 510. The first electrode E1 and the second electrode E2 may include a conductive material. The first electrode E1 and the second electrode E2 may include, for example, at least one of copper, silver, gold, and aluminum.

Subsequently, in each of the plurality of heating zones 1Z to 15Z, a heating member material layer 520a may be formed on the first surface 510a of the plate 510. The heating member material layer 520a may be formed between the first electrode E1 and the second electrode E2. The heating member material layer 520a may extend along the circumferential direction of the plate 510, in each of the plurality of heating zones 1Z to 15Z. The heating member material layer 520a may be deposited by using physical deposition (PVD) or chemical deposition (CVD). The drawings illustrate the first and second heating zones 1Z and 2Z, but embodiments of the present inventive concept are not limited thereto. In each of the plurality of heating zones 1Z to 15Z, the heating member material layer 520a may be formed on the first surface 510a of the plate 510.

The heating member material layer 520a may include a carbon nano compound. For example, the heating member material layer 520a may include graphene, carbon nanotubes (CNT, (for example, single-walled carbon nanotubes, double-walled carbon nanotubes, multi-walled carbon nanotubes, rope carbon nanotubes, and the like)), and carbon balls, and the like, but is not limited thereto.

Referring to FIG. 23, in the plurality of heating zones 1Z to 15Z, the plurality of heating members 520 may be patterned by using laser processing.

The laser LL may be irradiated on an upper surface of the heating member material layer 520a. In this case, the height of the heating member material layer 520a in the portion on which the laser LL is irradiated may be decreased. Accordingly, in each of the plurality of heating zones 1Z to 15Z, the heating member material layer 520a may be patterned to have a step. In an embodiment, in each of the plurality of heating zones 1Z to 15Z, the plurality of heating members 520 may include a stepped portion SL whose thickness in the third direction (Z direction) decreases as the distance from the center axis CX of the plate 510 increases.

When the laser LL is irradiated to the heating member material layer 520a, the heating member material layer 520a of the portion irradiated with the laser LL may be incompletely combusted. For example, when the heating member material layer 520a includes a carbon nano compound, the heating member material layer 520a of the portion irradiated with the laser LL may be converted to a carbonized compound.

Even in the case of a substrate processing apparatus 800 according to an embodiment, the plurality of heating members 520 may be a planar heating element extending along the circumferential direction of the plate 510. Accordingly, the area of the plurality of heating members 520 contacting the plate 510 may be increased compared to the case where the plurality of heating members 520 are linear heating elements. Accordingly, when it is desired to change the plate 510 to a preset temperature, the time required for the plate 510 in contact with the plurality of heating members 520 according to an embodiment to change to the preset temperature may be shortened.

In addition, the plurality of heating members 520 according to an embodiment are planar heating elements extending along the circumferential direction of the plate 510, in a plan view, the length of the inner side surface of the plurality of heating members 520 may be shorter than the length of an outer side surface. That is, in a plan view, the area of the plurality of heating members 520 may increase toward the outer side of the plate 510, and accordingly, the sheet resistance of the plurality of heating members 520 may decrease. Meanwhile, each of the plurality of heating members 520 according to an embodiment may include a stepped portion SL whose thickness in the third direction (Z direction) decreases as the distance from the center of the plate 510 increases. Accordingly, even if the sheet resistance of the plurality of heating members 520 increases toward the outer side of the plate 510, the resistance value according to the radial direction of the plate 510 of the plurality of heating members 520 may be maintained constant. Therefore, the temperature deviation of the heating support member 50 due to heating of the plurality of heating members 520 may be decreased, and reliability of the substrate processing apparatus 800 may be improved.

While the embodiment of the present disclosure has been described in connection with what is presently considered to be practical embodiments, it is to be understood that the disclosure is not limited to the disclosed embodiments, but, on the contrary, is intended to cover various modifications and equivalent arrangements included within the scope of the appended claims.

### DESCRIPTION OF SYMBOLS

800: substrate processing apparatus
1Z-15Z: plurality of heating zones
510: plate
500: heating plate
520: heating member
E1: first electrode
E2: second electrode
530: insulation layer
RTD: temperature sensor

What is claimed is:

1. A substrate supporting member, comprising:
a plate comprising at least one heating zone;
at least one heating member on a first surface of the plate, wherein the at least one heating member is in the at least one heating zone and extends along a circumferential direction of the plate, and wherein the at least one heating member is configured to heat a substrate supported by the plate;
a first electrode on the first surface of the plate, wherein the first electrode is connected to an inner side surface of the at least one heating member; and
a second electrode on the first surface of the plate, wherein the second electrode is connected to an outer side surface of the at least one heating member,
wherein the at least one heating member has a stair-step configuration such that a portion of the at least one heating member that is adjacent the first electrode has a first thickness that is greater than a second thickness of a portion of the at least one heating member that is adjacent the second electrode.

2. The substrate supporting member of claim 1, wherein the at least one heating member comprises:
a first heating member on the first surface of the plate; and
a second heating member on a first surface of the first heating member,
wherein a width of the first heating member is greater than a width of the second heating member.

3. The substrate supporting member of claim 2, wherein a first side surface of the second heating member is aligned with a first side surface of the first heating member.

4. The substrate supporting member of claim 2, wherein the at least one heating member comprises a third heating member on a first surface of the second heating member,
wherein the width of the second heating member is greater than a width of the third heating member.

5. The substrate supporting member of claim 4, wherein a sum of thicknesses of the first, second and third heating members is 1/25 or less of a thickness of the plate.

6. The substrate supporting member of claim 1, wherein the second electrode circumferentially extends along the outer side surface of the at least one heating member.

7. The substrate supporting member of claim 1, wherein the at least one heating member comprises a carbon nano compound.

8. The substrate supporting member of claim 7, wherein the first electrode and the second electrode comprise at least one of copper, silver, gold, and aluminum.

9. The substrate supporting member of claim 1, wherein the at least one heating zone comprises a plurality of heating zones arranged circumferentially around a central portion of the plate,
wherein the at least one heating member comprises a plurality of heating members with each of the plurality of heating members in a respective one of the plurality of heating zones, wherein each of the plurality of heating members has the stair-step configuration wherein a thickness of each heating member decreases as a distance from the central portion of the plate increases.

10. The substrate supporting member of claim 1, wherein:
the first electrode is in a central portion of the plate; and
the second electrode is radially spaced outward from the first electrode and extends around the first electrode in the circumferential direction of the plate.

11. The substrate supporting member of claim 10, wherein a thickness of the at least one heating member decreases as a distance from the central portion of the plate increases.

12. A substrate supporting member, comprising a plate;
at least one heating member on a first surface of the plate, wherein the at least one heating member is configured to heat a substrate supported by the plate, wherein the at least one heating member extends along a circumferential direction of the plate;
a first electrode connected to an inner side surface of the at least one heating member; and
a second electrode extending along the circumferential direction of the plate, and connected to an outer side surface of the at least one heating member,
wherein the at least one heating member comprises
a first heating member on the first surface of the plate; and
a second heating member on a first surface of the first heating member,
wherein a width of the first heating member is greater than a width of the second heating member.

13. The substrate supporting member of claim 12,
wherein the at least one heating member has a stair-step configuration such that a thickness of the at least one heating member decreases as a distance of the at least one heating member from a center of the plate increases.

14. The substrate supporting member of claim 12, wherein a first side surface of the second heating member is aligned with a first side surface of the first heating member.

15. The substrate supporting member of claim 12, wherein the heating member further comprises a third heating member on a first surface of the second heating member,
wherein a sum of thicknesses of the first, second and third heating members is 1/25 or less of a thickness of the plate.

16. The substrate supporting member of claim 15,
wherein the width of the second heating member is greater than a width of the third heating member.

17. A substrate supporting member, comprising:
a plate comprising a plurality of heating zones arranged circumferentially around a central portion of the plate;
a plurality of heating members on a first surface of the plate, wherein each heating member is in a respective heating zone, and wherein each heating member is configured to heat a substrate supported by the plate,
a first electrode in the central portion of the plate, wherein the first electrode is connected to an inner side surface of each of the plurality of heating members; and
a second electrode connected to an outer side surface of each of the plurality of heating members,
wherein each of the plurality of heating members has a stair-step configuration such that a thickness thereof decreases as a distance of each of the plurality of heating members from the central portion of the plate increases.

18. The substrate supporting member of claim 17, wherein each of the plurality of heating members comprises:
a first heating member on the first surface of the plate; and
a second heating member on a first surface of the first heating member,
wherein a width of the first heating member is greater than a width of the second heating member.

19. The substrate supporting member of claim 17, wherein the second electrode extends along the outer side surface of each of the plurality of heating members.

20. The substrate supporting member of claim 17, wherein each of the plurality of heating members comprises a carbon nano compound.
